(19) United States
(12) Patent Application Publication
(10) Pub. No.: US 2002/0038689 A1
(43) Pub. Date: Apr. 4, 2002

(54) Reduced and atmospheric pressure process capable epitaxial chamber

(76) Inventors: Rudolf Bayer, Moosburg (DE); Manfred Schiekofer, Freising (DE); Guenther Schmidt, Kranzberg (DE)

Correspondence Address: TEXAS INSTRUMENTS INCORPORATED, P O BOX 655474, M/S 3999, DALLAS, TX, 75265

(21) Appl. No.: 09/935,445

(22) Filed: Aug. 23, 2001

Related U.S. Application Data
(60) Provisional application No. 60/229,487, filed on Aug. 31, 2000.

(51) Int. Cl. C23F 1/02; C23C 16/00

(52) U.S. Cl. 156/345; 118/723 R

(57) ABSTRACT

An epitaxial growth chamber with a quartz dome that can withstand low pressure forces and also allows laminar flow in atmospheric pressure processes.

### BACKGROUND AND SUMMARY OF THE INVENTION

The present invention relates to integrated circuit structures and fabrication methods, and more particularly to the creation of epitaxial layers.

### BACKGROUND: EPITAXIAL GROWTH CHAMBERS

In IC circuit fabrication, epitaxial growth refers to the growth of a single crystal semiconductor film upon a substrate. Epitaxial growth in semiconductor device technology is important because of the ease with which the impurity concentration in the film can be controlled independently of the impurity concentration in the substrate. This is commonly done by controlling the constituent concentrations in the gas.

The most common way to grow epitaxial films is through high temperature chemical vapor deposition (CVD), where molecules are deposited on a wafer as products of chemical reactions occurring at the wafer surface.

Different quartz domes are used in epitaxial growth chambers for different process parameters. Two main categories of processing are atmospheric pressure epitaxial deposition, and reduced pressure epitaxial deposition. Atmospheric epi growth is done at high temperatures At atmospheric pressure, process gases have short mean free paths, which causes diffusion through the boundary layer a limitation to the process. Atmospheric processes are therefore more sensitive to variations in gas concentration, flow and exhaust rates than to temperature.

Reduced pressure epi growth also occurs at high temperature. Because of the low pressure of the system, diffusion constants are not as important to process control as the temperature. As the film grows on the substrate, the molecules need enough kinetic energy to migrate to their location in the growing crystal lattice. Low pressure epi growth is therefore more sensitive to temperature than to reactant flow rates. To withstand the mechanical stress of a low pressure system, the quartz dome has a convex shape to make it more resistant to pressure induced forces.

BICMOS and CMOS applications require different epitaxial deposition processes. The common technique for BICMOS is a reduced pressure (i.e., 20-80 Torr) process, also called an RP process. CMOS products are processes with an atmospheric pressure epi deposition (also called ATM deposition).

The shape of the quartz dome on the atmospheric pressure chamber is shaped to induce a high velocity laminar flow, limiting the total volume within the chamber to control flow rates but making the shape of the chamber inadequate to withstand the forces of a low pressure system. The RP dome is mechanically stable enough for atmospheric pressure conditions, but has too much turbulence to get good, repeatable epi film thickness parameters. Conversion from the atmospheric dome to the RP dome and vice versa is costly in time, manpower, and consumables.

There is therefore a need in the art for a way to avoid the costs incurred in serial processing at different pressures and in changing domes of epitaxial growth chambers.

Reduced and Atmospheric Pressure Process Capable Epitaxial Chamber

The present application discloses a new chamber for epitaxial growth. The new chamber combines the mechanical robustness of the reduced pressure chamber dome with the shape and flow control of the atmospheric pressure chamber. The result is a chamber wherein either reduced pressure or atmospheric pressure depositions can be performed without changing equipment.

In the preferred embodiment, the newly designed dome is made from a quartz piece with a slightly convex shape as used in reduced pressure domes, but with a 50% reduction in chamber volume to provide laminar reactant gas flow over the wafer. This combination of qualities allows the same chamber to be used serially for reduced pressure and atmospheric processes with no downtime for conversion.

Advantages of the disclosed methods and structures, in various embodiments, can include one or more of the following:

different processes can be implemented on the same chamber without loss of throughput, conversion time, manpower, or consumables;

potential for both low pressure and atmospheric pressure processes on the same wafer;

15% or more reduced gas consumption due to reduced volume.

### BRIEF DESCRIPTION OF THE DRAWINGS

The disclosed inventions will be described with reference to the accompanying drawings, which show important sample embodiments of the invention and which are incorporated in the specification hereof by reference, wherein:

FIG. 1 shows a conventional epitaxial growth chamber equipped to handle reduced pressure conditions.

FIG. 2 shows a conventional epitaxial growth chamber equipped to process wafers at atmospheric pressure conditions.

FIG. 3 shows a preferred embodiment of the present innovative fabrication chamber.

FIG. 4 shows an innovative dome according to the preferred embodiment.

FIG. 5a shows a chart comparing the uniformities of epitaxial layers grown in both a typical RP chamber and an innovative chamber.

FIG. 5b shows a chart comparing the uniformities of epitaxial layers grown in both a typical ATM chamber and an innovative chamber.

FIG. 5c shows a chart comparing the thicknesses of epi layers grown in both a typical RP chamber and an innovative chamber.

FIG. 5d shows a chart comparing the thicknesses of epi layers grown in both a typical ATM chamber and an innovative chamber.

### DETAILED DESCRIPTION OF THE PREFERRED EMBODIMENTS

The numerous innovative teachings of the present application will be described with particular reference to the presently preferred embodiment. However, it should be understood that this class of embodiments provides only a few examples of the many advantageous uses of the innovative teachings herein. In general, statements made in the specification of the present application do not necessarily delimit any of the various claimed inventions. Moreover, some statements may apply to some inventive features but not to others.

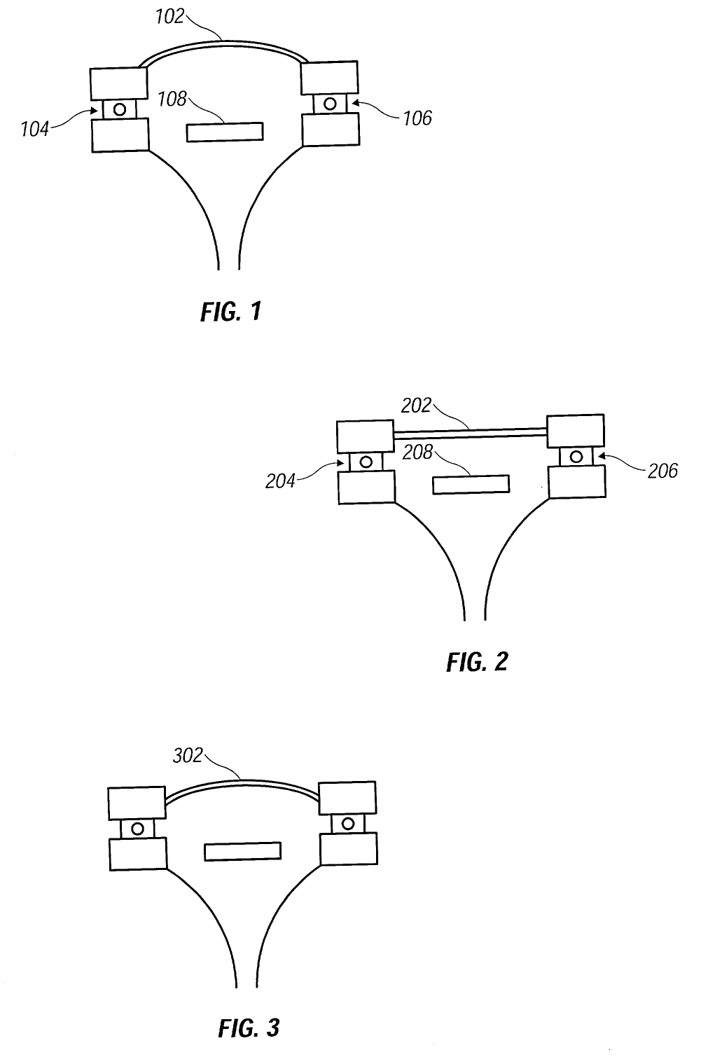

The preferred embodiment is described with reference to the several drawings. FIG. 1 shows a conventional epitaxial growth chamber equipped to handle reduced pressure conditions. The chamber includes an upper dome 102, a gas inlet 104 through which reactant gases are introduced to the chamber, a gas exhaust 106 for removing gases from the chamber, heating units (not shown), and a surface for placement of the wafer 108. The dome 102 of the chamber is a quartz piece that has a convex shape. The convex shape helps the dome withstand mechanical forces arising from the low pressure within the chamber.

FIG. 2 shows a conventional epitaxial growth chamber equipped to process wafers at atmospheric pressure conditions. This chamber includes an upper dome 202, a gas inlet 204 and exhaust 206, heating units, and a wafer holder surface 208. This chamber differs from the reduced pressure chamber mainly in the shape of the upper dome. Atmospheric processes are more susceptible to changes in reactant gas flow than reduced pressure processes. Atmospheric chambers must therefore be capable of creating a laminar flow over the wafer. To achieve this, a flat dome piece for the chamber is required because a convex dome's greater volume allows too much turbulence. Also, the increased mechanical strength of the convex dome is not needed in an atmospheric process because of the absence of pressure induced forces.

The RP domes for epitaxial growth chambers provide the necessary mechanical stability, but introduce too much turbulence into the reactant gas flow within the chamber. The turbulence is introduced because of the large volume of the chamber and the shape of its walls. The atmospheric chamber domes are flatter, providing laminar gas flow across the wafer, but they can't withstand the stress of a low pressure process environment.

FIG. 3 shows a preferred embodiment of the present innovative fabrication chamber. The dome 302 of the chamber is shaped so as to provide resistance against the mechanical stress introduced by the low pressure process. The dome is also shaped to provide the necessary reactant gas flow control as required in atmospheric pressure chambers. In the preferred embodiment, this blend is achieved by reducing the volume of the chamber by 50% while maintaining the basic convex shape of the dome. The combination of a convex shape and reduced volume provide a chamber that can accommodate both low pressure and high pressure processes without changing domes.

Reducing the total volume of the chamber increases reactant gas velocity through the chamber according to a relationship which states that

$$\frac{{v}_{s}}{{v}_{a}} = \frac{{V}_{a}}{{V}_{s}}$$

where vₛ and vₐ are gas velocities for the standard and atmospheric processes, and Vₛ and Vₐ are volumes of the standard and atmospheric chambers, respectively. This relationship shows that as chamber volumes decrease, their relative gas flow velocities increase. Higher gas velocity decreases turbulence.

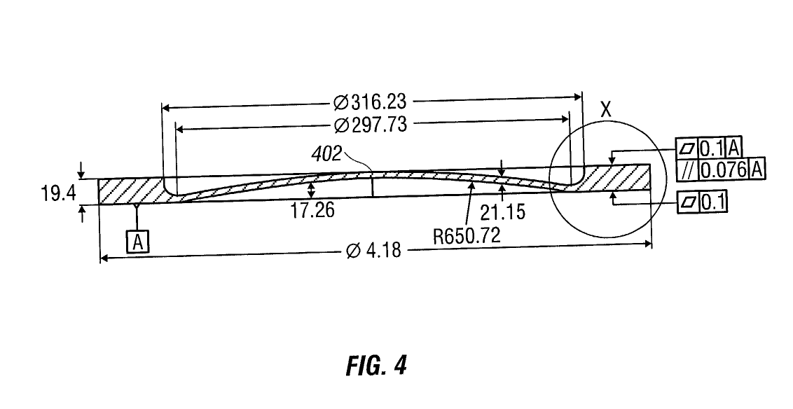

The innovative dome is described in FIG. 4. In the preferred embodiment, the dome 402 of the chamber has a diameter of 297.73 mm and a radius of curvature of 650.72 mm. The thickness of the quartz in the dome is approximately 17.26 mm near the center of the dome and 21.15 mm nearer the edge of the dome.

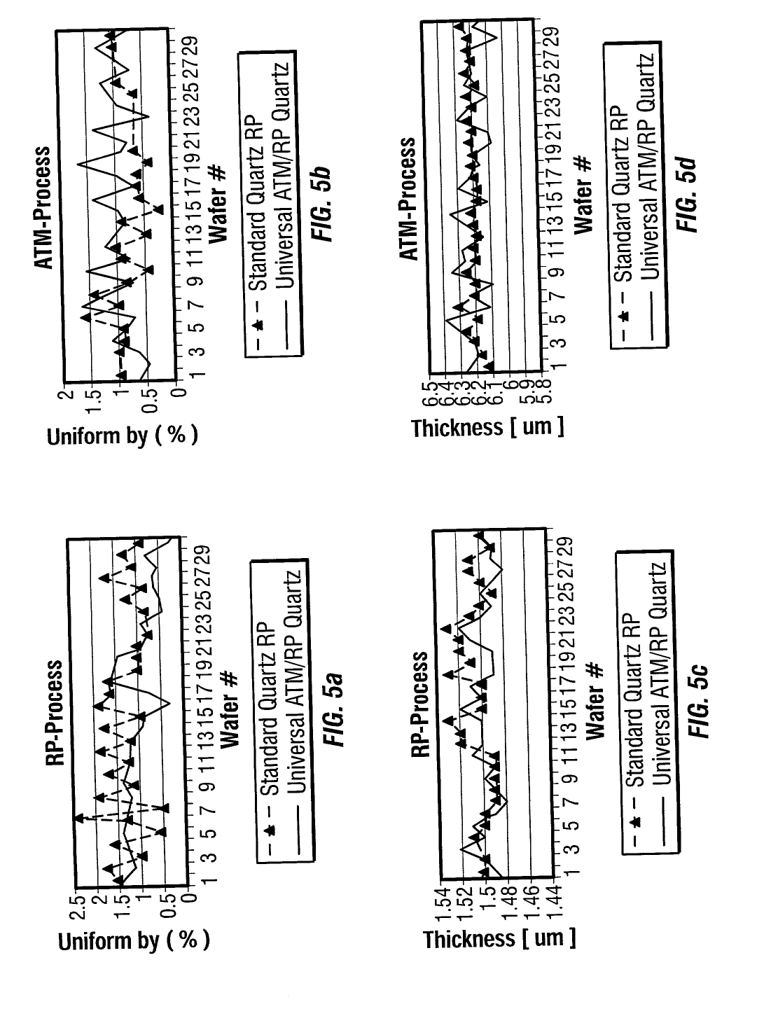

The experimental results of uniformity and thickness are discussed with reference to FIGS. 5a-5d. FIG. 5a shows data from the reduced pressure process. The solid line represents percent uniformity measurements of epitaxial layers from wafers processed in a chamber embodying a preferred embodiment of the present application using the Universal ATM/RP Quarts. The triangle data points represent percent uniformity measurements taken from wafers processed using the Standard RP Quartz dome. FIG. 5b compares uniformity of wavers grown in the innovative chamber with those grown in a Standard Quartz RP chamber. The charts measure uniformity over several wafers to test the reliability and repeatability of processes done in the different chambers. The chart shows that the innovative dome had uniformity equal to or better than the Standard Quartz RP dome and the Standard Quartz ATM dome.

FIG. 5c compares the thicknesses (in microns) of epitaxial layers of wafers grown in the Universal ATM/RP Quartz domed chamber with those grown using the Standard Quartz RP dome. FIG. 5d compares the thicknesses of epi layers done at atmospheric pressures using the innovative chamber and the Standard Quartz RP chamber.

The charts demonstrate that the quality of the epitaxial layers, measured as thickness and uniformity of the films, at least meets or even exceeds the current standards.

By reducing the total volume of a reduced pressure type chamber, the requirements for laminar reactant gas flow are achieved while still maintaining the resistance to mechanical stress required by low pressure processes. The chamber dome can be made in a range of shapes, so long as the dome itself fulfills the requirements of both RP and atmospheric processes. The radius of curvature of the convex dome can be as small as possible while not disturbing the necessary flow characteristics, or the radius of curvature can be made as large as possible (corresponding to a flatter dome) so long as the mechanical stresses of RP processes can be withstood. Though the preferred embodiment specifies exact dimensions for the dome shape, the innovations of the present application can be employed in other embodiments.

Using the innovative chamber, the quality of the epitaxial layers are as good as current standards require. Film thickness stability and uniformity at least meet or exceed the current standards. Because the epitaxial film resistivity is mainly determined by the deposition temperature and not by the flow pattern, there is no change in the resistivity stability and uniformity from old chambers to the new chamber design.

Definitions

Following are short definitions of the usual meanings of some of the technical terms which are used in the present application. (However, those of ordinary skill will recognize whether the context requires a different meaning.) Additional definitions can be found in the standard technical dictionaries and journals.

Convex: used to generally refer to a nonplanar shape for a dome. If a dome were not circular, the term convex would refer to a non-planar surface or shape to the dome.

Laminar Flow: refers to gas flow within the chamber that is not turbulence dominated.

Vacuum: a low pressure regime, below atmospheric pressure.

Modifications and Variations

As will be recognized by those skilled in the art, the innovative concepts described in the present application can be modified and varied over a tremendous range of applications, and accordingly the scope of patented subject matter is not limited by any of the specific exemplary teachings given, but is only defined by the issued claims.

The innovations of the present application can be used to shorten the process downtime between different pressure uses of an innovative chamber. The innovations can also be used to process a wafer at different pressures serially in the same process.

Additional general background, which help to show the knowledge of those skilled in the art regarding variations and implementations of the disclosed inventions, may be found in the following documents, all of which are hereby incorporated by reference: Silicon Processing for the VLSI Era, Vols. 1-3, S. Wolf, Lattice Press (1990); Microchip Fabrication, Peter Van Zant, McGraw-Hill (1997).

What is claimed is:

1. An integrated circuit fabrication unit, comprising:
a chamber which is shaped to provide laminar gas flow at substantially atmospheric pressure and mechanical stability at low pressure.

2. The chamber of claim 1, wherein said chamber includes a quartz dome.

3. The chamber of claim 2, wherein said dome has a convex shape.

4. An integrated circuit fabrication chamber, comprising:
a dome which is shaped to provide laminar gas flow at substantially atmospheric pressure and mechanical stability when a vacuum is applied to said chamber.

5. The chamber of claim 4, wherein said dome has a convex shape.

6. The chamber of claim 4, wherein said dome is quartz.

7. An integrated circuit fabrication unit, comprising:
a chamber with a dome, said chamber capable of low pressure processes and atmospheric processes without replacing said dome.

8. The chamber of claim 7, wherein said dome has a convex shape.

9. The chamber of claim 7, wherein said dome is quartz.

10. An integrated circuit fabrication unit, comprising:
a chamber with an input and an exhaust;
a dome forming part of said chamber, said dome providing laminar flow under atmospheric pressure and resistance to pressure induced forces at low pressure.

11. The chamber of claim 10, wherein said dome has a convex shape.

12. The chamber of claim 10, wherein said dome is quartz.

13. An integrated circuit fabrication unit, comprising:
a chamber with an input and exhaust, said chamber providing mechanical stability for low pressure processes and laminar gas flow at atmospheric pressure.

14. The chamber of claim 13, wherein said dome has a convex shape.

15. The chamber of claim 13, wherein said dome is quartz.

16. An integrated circuit fabrication unit, comprising:
a chamber;
a dome forming part of said chamber, said dome having a convex shape with a curvature that does not introduce turbulence in an atmospheric flow regime.

17. The chamber of claim 16, wherein said dome is quartz.

18. An integrated circuit fabrication unit, comprising:
a chamber;
a dome forming part of said chamber, said dome having a convex shape and a radius of curvature substantially as large as possible while still reliably providing resistance to reduced pressure forces.

19. An integrated circuit fabrication unit, comprising:
a chamber;
a dome forming part of said chamber, said dome having a convex shape and a radius of curvature substantially as small as possible while still reliably providing laminar gas flow.
